(19) United States
(12) Patent Application Publication
(10) Pub. No.: US 2019/0386119 A1
(43) Pub. Date: Dec. 19, 2019

(54) METHOD OF STABLIZING IGZO THIN FILM TRANSISTOR

(71) Applicant: Shenzhen China Star Optoelectronics Semiconductor Display Technology Co., Ltd., Shenzhen, Guangdong (CN)

(72) Inventor: Longqiang SHI, Shenzhen, Guangdong (CN)

(21) Appl. No.: 15/740,692

(22) PCT Filed: Nov. 23, 2017
(86) PCT No.: PCT/CN2017/112574

§ 371 Date: Dec. 28, 2017

(30) Foreign Application Priority Data
Nov. 16, 2017 (CN) 201711139924.X

(51) Int. Cl. H01L 29/66; H01L 21/56; H01L 29/786; H01L 21/311; H01L 21/02

(52) U.S. Cl. CPC H01L 29/66969; H01L 21/56; H01L 21/02164; H01L 21/31116; H01L 29/7869

(57) ABSTRACT

This invention provides a method for improving the stability of the IGZO thin film transistors. The method comprises providing IGZO thin film transistors on a substrate; forming a passivation layer on the IGZO thin film transistors; and performing a hydrophobization process on the passivation layer to form hydrophobic groups on the passivation layer. This invention provides a way to improve the stability of IGZO thin film transistors. The water proof function of the passivation layer of the IGZO thin film transistors is improved as well. The drift issues of the negative threshold voltage of the IGZO thin film transistors are solved. The outranged threshold voltage and disfunction of the IGZO thin film transistor are avoided.

### RELATED APPLICATIONS

The present application is a National Phase of International Application Number PCT/CN2017/112574, filed Nov. 23, 2017, and claims the priority of China Application No. 201711139924.X, filed Nov. 16, 2017.

### FIELD OF THE DISCLOSURE

This invention relates to the display technology, especially relates to a method of stabilizing the IGZO thin film transistors.

### BACKGROUND

FIG. 1 shows a Back Channel Etched indium gallium zinc oxide thin film transistor (BCE type IGZO TFT). The IGZO TFT 2 comprises a gate 21, a gate dielectric layer 22, an IGZO thin film 23, a source 25 and a drain 24 on a substrate 1. The IGZO TFT 2 is easily to be form as a depletion mode TFT. The threshold voltage Vth is negative and the IGZO TFT is very sensitive to ambient water. If water penetrates into the IGZO TFT through the back channel, the threshold voltage, Vth, will become extremely negative and the IGZO TFT 2 will fail as well. To solve the issue mentioned above, the current technology is to form passivation layer on the TFT. FIG. 2 shows a structure with a first passivation layer 31 on the IGZO TFT 2. The first passivation layer 31 is SiOₓ and x≥1. FIG. 3 shows a structure with a first passivation layer 31 and a second passivation layer 32 on the IGZO TFT 2. The second passivation layer 32 is formed with organic materials, such as Perfluoroalkoxy(PFA) resin material. FIG. 4 shows a structure with a first passivation layer 31, a second passivation layer 32 and a third passivation layer 33 on the IGZO TFT 2. The first passivation layer 31, the second passivation layer 32 and the third passivation layer 33 are formed as the passivation layer 3 of the IGZO TFT 2. The third passivation layer 33 is formed with inorganic materials; such as one or two of the group consisting of SiOₓ, SiNOₓ, and SiNₓ. However, due to the manufacturing limitation, those passivation layers are not dense enough to prevent the IGZO TFT 2 from water.

### SUMMARY

To solve the issues mentioned above, this invention provides a method to improve the stability of the IGZO TFT. The function of blocking water in the passivation layer is improved to solve the threshold voltage drifting issue of the IGZO TFT and the outranged threshold voltage and the IGZO TFT failure are avoided as well.

This invention provides a method of stabilizing the IGZO thin film transistor It comprises: providing IGZO thin film transistors on a substrate; forming a passivation layer on the IGZO thin film transistors; and performing a hydrophobization process on the passivation layer to form hydrophobic groups on the passivation layer.

Preferably, the step of forming IGZO thin film transistors on the substrate comprises the following steps: forming a gate on the substrate; forming a gate dielectric layer on the substrate, wherein the gate dielectric layer covers the gate; and forming a IGZO thin film; a source and a drain on the dielectric layer, wherein the source, the drain and the IGZO thin film are overlap partially.

Preferably, the step of performing a hydrophobization process on the passivation layer comprises treating the passivation layer with Fluoride ions.

Preferably, the step of treating the passivation layer with Fluoride ions comprises: mixing the oxygen and one of the group consisting of CF₄ or SF₆ to form a gas mixture; ionizing the gas mixture to form a ionized gas mixture; and dry etching the passivation with the ionized gas mixture.

Preferably, the step of forming a passivation layer on the IGZO thin film transistors comprises: forming a first passivation layer on the IGZO thin film transistor, wherein the first passivation layer is SiOₓ and x≥1.

Preferably, the step of forming a passivation layer on the IGZO thin film transistors comprises: forming a second passivation layer on the first passivation layer, wherein the second passivation layer is Perfluoroalkoxy resin layer.

Preferably, the step of forming a passivation layer on the IGZO thin film transistors comprises: forming a third passivation layer on the second passivation layer, wherein the third passivation layer comprises SiOₓ, SiNO_{y}, and SiNz and y≥1, and z≥1.

Preferably, the step of performing a hydrophobization process on the passivation layer comprises: performing a hydrophobization process on the first passivation layer.

Preferably, the step of performing a hydrophobization process on the passivation layer comprises: performing a hydrophobization process on the second passivation layer.

Preferably, the step of performing a hydrophobization process on the passivation layer comprises: performing a hydrophobization process on the third passivation layer.

This invention also provides a method of stabilizing IGZO thin film transistors. It comprises: providing IGZO thin film transistors on a substrate; forming a passivation layer on the IGZO thin film transistors; and performing a hydrophobization process on the passivation layer to form hydrophobic groups on the passivation layer, wherein the step of forming IGZO thin film transistors on the substrate comprises: forming a gate on the substrate; forming a gate dielectric layer on the substrate, wherein the date dielectric layer covers the gate; and forming an IGZO thin film, a source and a drain on the dielectric layer, wherein the source, the drain and the IGZO thin film are overlap partially.

Preferably, the step of performing a hydrophobization process on the passivation layer comprises: treating the passivation layer with Fluoride ions.

Preferably, the step of treating the passivation layer with Fluoride ions comprises: mixing the oxygen and one of the group consisting of CF4 or SF6 to form a gas mixture; ionizing the gas mixture to form a ionized gas mixture; and dry etching the passivation with the ionized gas mixture.

Preferably, the step of forming a passivation layer on the IGZO thin film transistors comprises: forming a first passivation layer on the IGZO thin film transistor, wherein the first passivation layer is SiOₓ and x≥1.

Preferably the step of forming a passivation layer on the IGZO thin film transistors comprises: forming a second passivation layer on the first passivation layer, wherein the second passivation layer is Perfluoroalkoxy resin layer.

Preferably, the step of forming a passivation layer on the IGZO thin film transistors comprises: forming a third passivation layer on the second passivation layer, wherein the third passivation layer comprises SiOₓ SiNO_{y}, and SiN_{z} and y≥1, and z≥1.

Preferably, the step of performing a hydrophobization process on the passivation layer comprises: performing a hydrophobization process on the second passivation layer.

Preferably, the step of performing a hydrophobization process on the passivation layer comprises: performing a hydrophobization process on the second passivation layer.

Preferably, the step of performing a hydrophobization process on the passivation layer comprises: performing a hydrophobization process on the third passivation layer.

This invention has several advantages, such as: This invention provides a way to improve the stability of IGZO thin film transistors. The water proof function of the passivation layer of the IGZO thin film transistors is improved as well. The drift issues of the negative threshold voltage of the IGZO thin film transistors are solved. The outranged threshold voltage and disfunction of the IGZO thin film transistor are avoided.

### BRIEF DESCRIPTION OF THE DRAWINGS

FIG. 1 is a schematic structure of IGZO TFT.

FIG. 2 is a schematic structure of IGZO TFT with a first passivation layer.

FIG. 3 is a schematic structure of IGZO TFT with a first passivation layer and a second passivation layer.

FIG. 4 is a schematic structure of IGZO TFT with a first passivation layer, a second passivation layer and a third passivation layer.

FIG. 5 is a schematic diagram of a method for stabilizing IGZO TFT of the present invention.

FIG. 6 is a schematic structure of IGZO TFT of the first embodiment of the present invention.

FIG. 7 is a schematic structure of IGZO TFT of the second embodiment of the present invention.

FIG. 8 is a schematic structure of IGZO TFT of the third embodiment of the present invention.

FIG. 9 is a schematic structure of IGZO TFT of the fourth embodiment of the present invention.

FIG. 10 is a schematic structure of IGZO TFT of the fifth embodiment of the present invention.

FIG. 11 is a schematic structure of IGZO TFT of the sixth embodiment of the present invention.

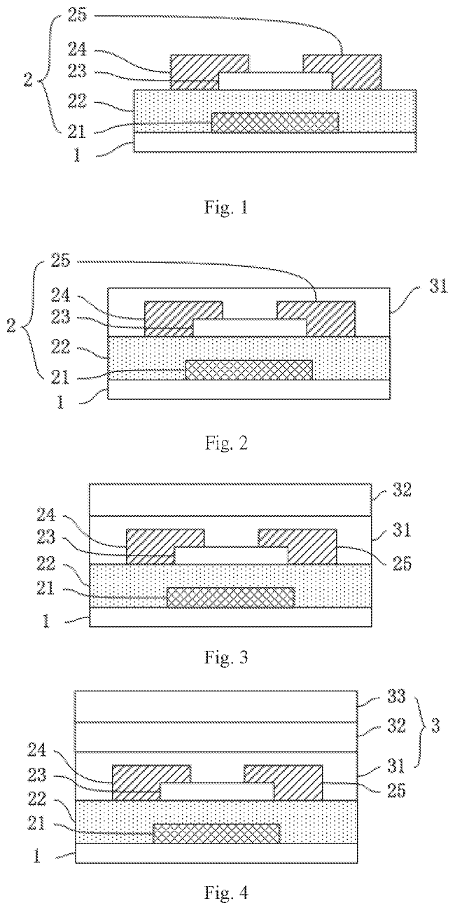

### DETAILED DESCRIPTION OF PREFERRED EMBODIMENTS

In order to make the purpose, technical solutions and advantages of the present invention more comprehensible, the present invention is further described in detail below with reference to the accompanying drawings and embodiments. It should be understood that the specific embodiments described herein are only used to explain the present invention, and are not intended to limit the present invention.

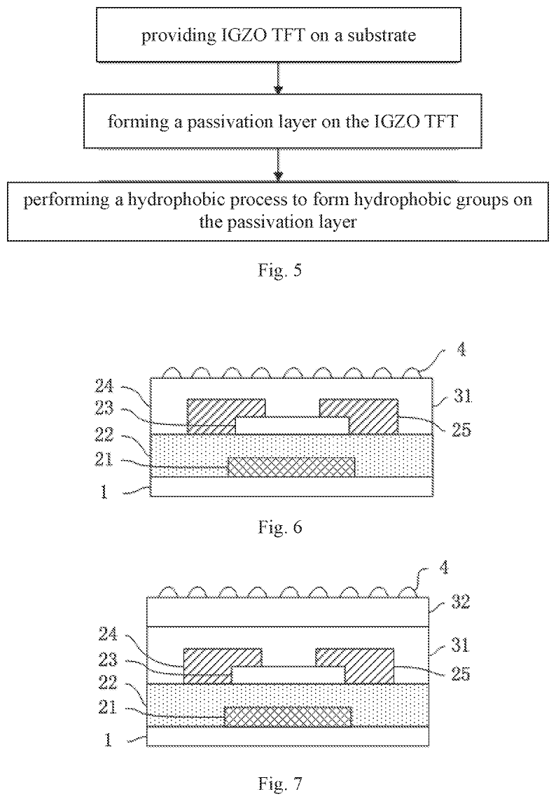

This invention provides a method of stabilizing IGZO thin film transistor. As showed in FIG. 5, the method comprises: providing IGZO thin film transistors 2 on a substrate 1; forming a passivation layer on the IGZO thin film transistors 2; performing a hydrophobization process on the passivation layer to form hydrophobic groups on the passivation layer.

To be specific, the passivation layer is on top of the substrate 1 and the passivation layer covers the IGZO thin film transistors.

Moreover; the step of forming IGZO thin film transistors 2 on the substrate 1 comprises: forming a gate 21 on the substrate 1; forming a gate dielectric layer 22 on the substrate 1; wherein the gate dielectric layer 22 covers the gate 21; and forming a IGZO thin film 23; a source 25 and a drain 24 on the dielectric layer 22, wherein the source 25, the drain 24 and the IGZO thin film 23 are overlap partially. The portions of the source 25, and the drain 24 which are partially overlapped are on top of the IGZO thin film 23.

To be specific; the step of performing a hydrophobization process on the passivation layer comprises: treating the passivation layer with fluoride ions.

The step of treating the passivation layer with Fluoride ions comprises: mixing the oxygen and one of the group consisting of CF₄ or SF₆ to form a gas mixture; ionizing the gas mixture to form an ionized gas mixture; and dry etching the passivation with the ionized gas mixture.

The gas mixture with fluoride ions is obtained after ionizing the CF₄ or SF₆.

After the dry etching is done, there are some residue of the group of the fluorine ions on the surface of the passivation layer. The fluorine ion group are hydrophobic and can act as the hydrophobic groups, so that the etched surface of the passivation layer is hydrophobic. This effectively prevent the ambient water from penetrating the passivation and affecting the electrical property of the IGZO TFT.

To be more specific, the step of forming a passivation layer on the IGZO thin film transistors 2 comprises: forming a first passivation layer 31 on the IGZO thin film transistor 2. The first passivation layer is formed with inorganic materials.

The step of forming a passivation layer on the IGZO thin film transistors 2 further comprises; forming a second passivation layer 32 on the first passivation layer 31. The second passivation layer 32 is formed with organic materials. Preferably, the second passivation layer 32 can act as the planarization layer. Comparing the inorganic materials, the organic materials are easily formed with a larger thickness to act as a planarization layer.

The step of forming a passivation layer on the IGZO thin film transistors comprises: forming a third passivation layer 33 on the second passivation layer 32. The third passivation layer is formed with inorganic materials.

To be specific, the first passivation 31 is formed with SiOₓ, the third passivation layer 33 is formed with at least one of the materials selected from the following group consisting of SiOₓ, SiNO_{y}, and SiN_{z}, wherein the x≥1, y≥1, and z≥1. The second passivation layer 32 is formed with Perfluoroalkoxy resin.

In this embodiment, the step of performing a hydrophobization process on the passivation layer comprises; performing a hydrophobization process on the first passivation layer 31.

In anther embodiment, the step of performing a hydrophobization process on the passivation layer comprises: performing a hydrophobization process on the second passivation layer 32.

In the other embodiment, the step of performing a hydrophobization process on the passivation layer comprises: performing a hydrophobization process on the third passivation layer 33.

In the first embodiment of the present invention, with reference to FIG. 6, a first passivation 31 is formed on the IGZO TFT 2 and fluoride ions are adapted to perform a hydrophobization process on the surface of the first passivation layer 31. The hydrophobic groups 4 are formed on the surface of the first passivation layer 31.

In the second embodiment of the present invention, with reference to FIG. 7, a first passivation layer 31 and a second passivation 32 are formed on the IGZO TFT 2 and fluoride ions are adapted to perform a hydrophobization process on the surface of the second passivation layer 32. The hydrophobic groups 4 are formed on the surface of the second passivation layer 32.

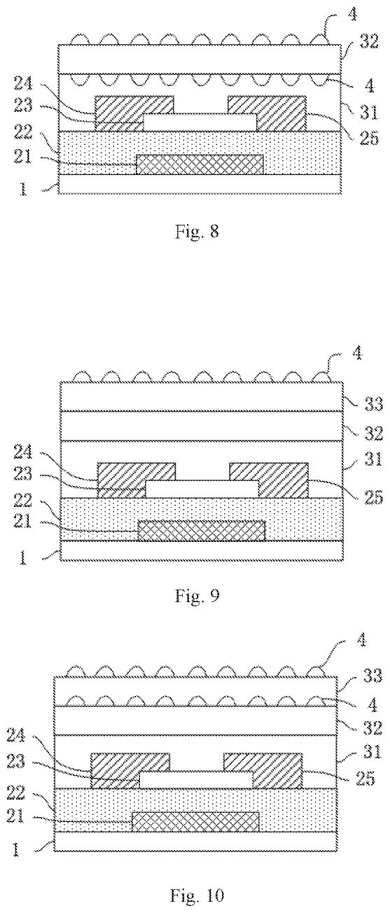

In the third embodiment of the present invention, with reference to FIG. 8, a first passivation is formed on the IGZO TFT 2 and fluoride ions are adapted to perform a hydrophobization process on the surface of the first passivation layer 31. The hydrophobic groups 4 are formed on the surface of the second passivation layer 32. Subsequently, a second passivation layer 32 is formed on the first passivation layer 31 and fluoride ions are adapted to perform a hydrophobization process on the surface of the second passivation layer 32. The hydrophobic groups 4 are formed on the surface of the second passivation layer 32.

In the fourth embodiment of the present invention, with reference to FIG. 9, a first passivation layer 31, a second passivation layer 32 and a third passivation 33 are formed on the IGZO TFT 2 and fluoride ions are adapted to perform a hydrophobization process on the surface of the third passivation layer 33. The hydrophobic groups 4 are formed on the surface of the third passivation layer 33

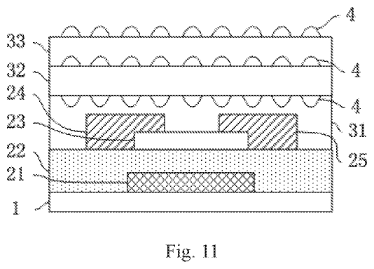

In the fifth embodiment of the present invention, with reference to FIG. 10, a first passivation layer 31 and a second passivation layer 32 are formed on the IGZO TFT 2 and fluoride ions are adapted to perform a hydrophobization process on the surface of the second passivation layer 32. The hydrophobic groups 4 are formed on the surface of the third passivation layer 32. Subsequently, a third passivation layer 33 is formed on the second passivation layer and fluoride ions are adapted to perform a hydrophobization process on the surface of the third passivation layer 33. The hydrophobic groups 4 are formed on the surface of the third passivation layer 33.

In the sixth embodiment of the present invention, with reference to FIG. 11, a first passivation is formed on the IGZO TFT 2 and fluoride ions are adapted to perform a hydrophobization process on the surface of the first passivation layer 31. The hydrophobic groups 4 are formed on the surface of the first passivation layer 31. Subsequently, a second passivation layer 32 is formed on the first passivation layer 31 and fluoride ions are adapted to perform a hydrophobization process on the surface of the second passivation layer 32. The hydrophobic groups 4 are formed on the surface of the second passivation layer 32. Subsequently, a third passivation layer 33 is formed on the second passivation layer and fluoride ions are adapted to perform a hydrophobization process on the surface of the third passivation layer 33. The hydrophobic groups 4 are formed on the surface of the third passivation layer 33.

Generally, when there are the first passivation layer 31, the second passivation layer 32 and the third passivation layer 31 on the IGZO TFT 2, and each passivation layer is with the hydrophobic groups, the water proof function is best among those embodiments.

In all, this invention provides a way to perform a hydrophobic process on passivation layer which is on top of the IGZO thin film transistors 2. The water proof function of the passivation layer of the IGZO thin film transistors 2 is improved. The drift issues of the negative threshold voltage of the IGZO thin film transistors are solved. The outranged threshold voltage and disfunction of the IGZO thin film transistor are avoided

The above descriptions are merely specific implementation manners of the present application. It should be noted that those skilled in the art may make some improvements and modifications without departing from the principle of the present application. These improvements and modifications should be regarded as the scope of protection of this application,

What is claimed is:

1. A method of stabilizing the IGZO thin film transistor, comprising:
providing IGZO thin film transistors on a substrate;
forming a passivation layer on the IGZO thin film transistors; and
performing a hydrophobization process on the passivation layer to form hydrophobic groups on the passivation layer.

2. The method according to claim 2, wherein the step of forming IGZO thin film transistors on the substrate comprises:
forming a gate on the substrate;
forming a gate dielectric layer on the substrate, wherein the gate dielectric layer covers the gate; and
forming a IGZO thin film; a source and a drain on the dielectric layer; wherein the source, the drain and the IGZO thin film are overlap partially.

3. The method according to claim 1; wherein the step of performing a hydrophobization process on the passivation layer comprises: treating the passivation layer with Fluoride ions.

4. The method according to claim 3, wherein the step of treating the passivation layer with Fluoride ions comprises:
mixing the oxygen and one of the group consisting of CF4 or SF6 to form a gas mixture;
ionizing the gas mixture to form a ionized gas mixture; and
dry etching the passivation with the ionized gas mixture.

5. The method according to claim 1, wherein the step of forming a passivation layer on the IGZO thin film transistors comprises:
forming a first passivation layer on the IGZO thin film transistor, wherein the first passivation layer is SiOₓ and x≥1.

6. The method according to claim 5, wherein the step of forming a passivation layer on the IGZO thin film transistors comprises:
forming a second passivation layer on the first passivation layer, wherein the second passivation layer is Perfluoroalkoxy resin layer.

7. The method according to claim 6, wherein the step of forming a passivation layer on the IGZO thin film transistors comprises:
forming a third passivation layer on the second passivation layer, wherein the third passivation layer comprises SiOₓ, SiNO_{y}, and SiN_{z} and z≥1.

8. The method according to claim 5, the step of performing a hydrophobization process on the passivation layer comprises:
performing a hydrophobization process on the first passivation layer.

9. The method according to claim 6, the step of performing a hydrophobization process on the passivation layer comprises:
performing a hydrophobization process on the second passivation layer.

10. The method according to claim 6, the step of performing a hydrophobization process on the passivation layer comprises:
performing a hydrophobization process on the third passivation layer.

11. A method of stabilizing the IGZO thin film transistor, comprising:
providing IGZO thin film transistors on a substrate;
forming a passivation layer on the IGZO thin film transistors; and
performing a hydrophobization process on the passivation layer to form hydrophobic groups on the passivation layer,
wherein the step of forming IGZO thin film transistors on the substrate comprises:
forming a gate on the substrate;
forming a gate dielectric layer on the substrate, wherein the gate dielectric layer covers the gate; and
forming an IGZO thin film, a source and a drain on the dielectric layer, wherein the source, the drain and the IGZO thin film are overlap partially.

12. The method according to claim 11, wherein the step of performing a hydrophobization process on the passivation layer comprises:
treating the passivation layer with Fluoride ions.

13. The method according to claim 12, wherein the step of treating the passivation layer with Fluoride ions comprises:
mixing the oxygen and one of the group consisting of CF4 or SF6 to form a gas mixture;
ionizing the gas mixture to form a ionized gas mixture; and
dry etching the passivation with the ionized gas mixture.

14. The method according to claim 11, wherein the step of forming a passivation layer on the IGZO thin film transistors comprises:
forming a first passivation layer on the IGZO thin film transistor, wherein the first passivation layer is SiOₓ and x≥1.

15. The method according to claim 14, wherein the step of forming a passivation layer on the IGZO thin film transistors comprises:
forming a second passivation layer on the first passivation layer, wherein the second passivation layer is Perfluoroalkoxy resin layer.

16. The method according to claim 15, wherein the step of forming a passivation layer on the IGZO thin film transistors comprises:
forming a third passivation layer on the second passivation layer; wherein the third passivation layer comprises SiOₓ, SiNO_{y}, SiN_{z} and y≥1, and z≥1.

17. The method according to claim 15, the step of performing a hydrophobization process on the passivation layer comprises:
performing a hydrophobization process on the second passivation layer.

18. The method according to claim 16, the step of performing a hydrophobization process on the passivation layer comprises:
performing a hydrophobization process on the second passivation layer.

19. The method according to claim 16, the step of performing a hydrophobization process on the passivation layer comprises:
performing a hydrophobization process on the third passivation layer.
